(19) United States
(12) Patent Application Publication
(10) Pub. No.: US 2009/0051000 A1
(43) Pub. Date: Feb. 26, 2009

(54) SEMICONDUCTOR DEVICE STRUCTURE

(76) Inventors: JENG GONG, Hsinchu City (TW); Wen-Chun Chung, Fongshan City (TW); Ru-Yi Su, Kouhu Township (TW); Fu-Hsiung Yang, Jhongli City (TW)

Correspondence Address: HOLLAND & KNIGHT LLP, 10 ST. JAMES AVENUE, 11th Floor, BOSTON, MA, 02116-3889, US

(21) Appl. No.: 12/194,806

(22) Filed: Aug. 20, 2008

(30) Foreign Application Priority Data
Aug. 21, 2007 (TW) 096130880

(51) Int. Cl. H01L 29/06

(52) U.S. Cl. 257/493; 257/E29.008

(57) ABSTRACT

A semiconductor device structure is provided. By placing an insulating dielectric material in the drift region of a device to modulate the electric field distribution and current flow in the drift region, the breakdown voltage of the device is increased while the turn-on impedance of the device is reduced.

### RELATED APPLICATION

This application claims the benefit of priority based on Taiwan Patent Application No. 096130880 filed on 21 Aug. 2007, the disclosure of which is incorporated herein by reference in its entirety.

### BACKGROUND OF THE INVENTION

1. Field of the Invention

The present invention relates to a semiconductor device structure. More particularly, the present invention relates to a semiconductor device structure that arranges an insulating dielectric region in a semiconductor device to increase a breakdown voltage.

2. Descriptions of the Related Art

Power devices have been widely used in power electronic fields. Such devices normally have to withstand a considerably high voltage, and when a power device is turned on, a large current is often expected to flow therethrough. Consequently, power devices consume a considerable amount of power.

Therefore, breakdown voltages and turn-on impedances have become two of the greatest factors in designing power devices. Although power devices are designed to deliver both a high breakdown voltage and a low turn-on impedance, it is usually difficult to meet these requirements simultaneously for the following reasons. First, the conventional practice used to obtain a high breakdown voltage is to lower the doping level of extrinsic atoms in the power device. However, this will cause the power device to provide less conductive ions when being turned on, thus resulting in an increased turn-on impedance. In other words, the breakdown voltage is inversely proportional to the doping level: the lower the doping level, the higher the breakdown voltage of the device. At the same time, as shown in the following equation, the higher the breakdown voltage, the higher the impedance of the device. For a device presenting a one-dimensional electric field, the impedance and the breakdown voltage will exhibit the following squared relationship:

$$Ron = \frac{4 {V}_{B}^{2}}{{ɛ}_{s} {μ}_{n} {E}_{c}^{3}} \qquad ( Equation 1 )$$

Additionally, for a typical PN semiconductor junction, the electric field therein is distributed in a one-dimensional form when a reverse bias is applied. In this case, a curvilinear integral of the electric field (i.e., BV=∫Edx) will result in a breakdown voltage that the junction can withstand under ideal conditions.

Based on this theory, a super junction structure has been proposed as an improved structure, as shown in FIG. 1. In FIG. 1, regions 11 and 13 are P-doped regions, while regions 12, 14 and 15 are N-doped regions. The super junction structure works under the following principle. A PN junction electric field perpendicular to an original breakdown electric field is established in a lightly doped region (i.e., the so-called drift region) to form a two-dimensional spatial electric field. Because the integral of an electric field represents the voltage, the voltage represented by the two-dimensional electric field is higher than that represented by the one-dimensional electric field. Accordingly, a power device that has a super junction structure will exhibit a higher breakdown voltage. However, charge balance needs to be considered in a power device with the super junction structure; that is, the P-type semiconductor and the N-type semiconductor included in the power device must have an equal amount of charges. To obtain the maximum breakdown voltage and the minimum turn-on impedance in a power device with the super junction structure, the P-type semiconductor and the N-type semiconductor must be depleted completely at the same time when a reverse bias is applied, which will present increased difficulty in the design and manufacturing process of the device. As indicated by Equation 2, the relationship between the breakdown voltage and the turn-on impedance is linear, where d represents the length of a current flow path. As compared to Equation 1, an improvement is obtained in Equation 2 in terms of the relationship between the breakdown voltage and the turn-on impedance.

$$Ron = \frac{{V}_{B} d}{( {μ}_{n} + {μ}_{p} ) {ɛ}_{s} {E}_{c}^{2}} \qquad ( Equation 2 )$$

However, the concern of charge balance in a power device with a super junction structure leads to an increased difficulty in the manufacturing process. Accordingly, there is still a need in the art for a power device structure that has an increased breakdown voltage, a decreased turn-on impedance, and a less difficult manufacturing process.

### SUMMARY OF THE INVENTION

One objective of this invention is to provide a semiconductor device structure. By placing at least an insulating dielectric material in a semiconductor region of a semiconductor device to alter the electric field distribution and current flow direction in the semiconductor region, a breakdown voltage of the device is increased.

According to this invention, by arranging at least an insulating dielectric material in the semiconductor region, the electric field distribution in the semiconductor region is modulated from one-dimensional to two-dimensional or even three-dimensional to increase the breakdown voltage of the device. Meanwhile, the turn-on impedance is decreased by shortening the length or increasing the doping level of the semiconductor region. The arrangement of the insulating dielectric material in the semiconductor region has no influence on either the charge balance or the characteristics of the device. Furthermore, this invention allows the use of a simple manufacturing process, and can be manufactured through a semiconductor manufacturing process incorporating a trench forming step.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 is a schematic view of a semiconductor device structure of the prior art;

FIG. 2 is a schematic view of a structure in accordance with the preferred embodiment of this invention;

FIG. 3 is a simulation diagram of the current distribution in the preferred embodiment;

FIG. 4 is a simulation diagram of the electric field distribution in the preferred embodiment;

FIG. 5 is a schematic view of a structure in accordance with another preferred embodiment of this invention;

FIG. 6(a) is a schematic view of structure in accordance with yet another preferred embodiment of this invention;

FIG. 6(b) is a schematic view of structure in accordance with still another preferred embodiment of this invention;

FIG. 6(c) is a schematic view of structure in accordance with yet a further preferred embodiment of this invention;

FIG. 6(d) is a schematic top view of the embodiment shown in FIG. 6(b); and

FIG. 6(e) is a schematic view of structure in accordance with still a further preferred embodiment of this invention.

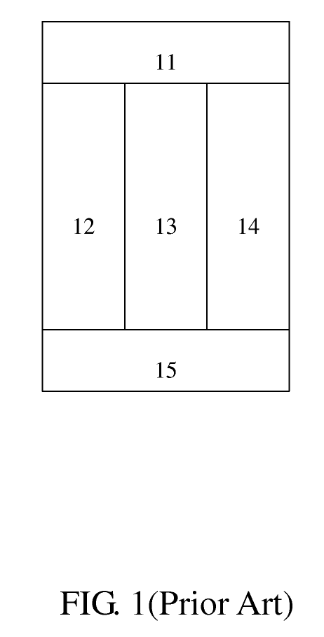

### DESCRIPTION OF THE PREFERRED EMBODIMENT

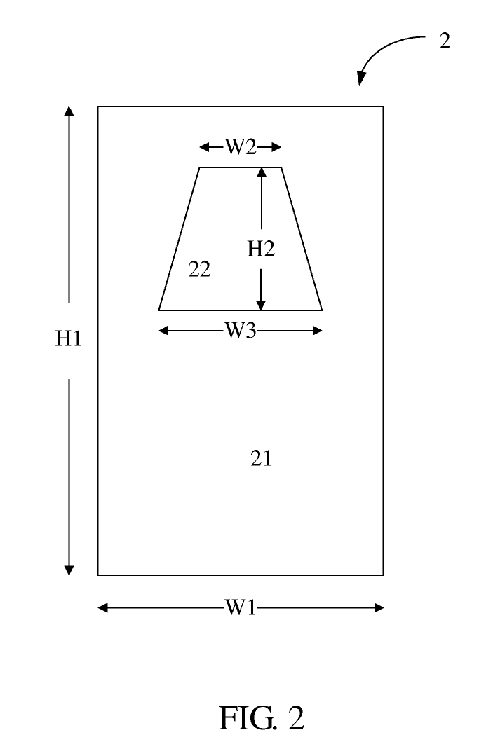

In reference to FIGS. 2, 3 and 4, the preferred embodiment of this invention, a schematic current simulation diagram thereof and a schematic electric distribution diagram thereof are illustrated therein respectively. In this embodiment, a semiconductor device structure 2 comprises a semiconductor region 21 and an insulating dielectric region 22 formed within the semiconductor region 21. The semiconductor region 21 is adapted to present an electric field when is applied with a voltage. The insulating dielectric region 22 is adapted to modulate the distribution of the electric lines of force in the semiconductor region 21. In this embodiment, the semiconductor region 21 may be considered a drift region in which extrinsic atoms such as P-type atoms or N-type atoms are doped. Meanwhile, the insulating dielectric region 22 is made of a material selected from a group consisting of silica, silicon nitride, high-dielectric coefficient materials used in a semiconductor manufacturing process and low-dielectric coefficient materials used in a semiconductor manufacturing process. In other embodiments, the insulating dielectric region may also be an interval space because an interval space containing air or in a vacuum may also provide electric insulation.

The semiconductor region 21 in this embodiment is provided with a first longitudinal dimension H1 and a first lateral dimension W1, while the insulating dielectric region 22 is provided with a second longitudinal dimension H2, a second lateral dimension W2 and a third lateral dimension W3. In this embodiment, H2 is smaller than or equal to H1, and W2 or W3 is also smaller than or equal to W1. Furthermore, when an electric field is applied to the semiconductor region 21, the electric lines of the force in the areas of the semiconductor region 21 near the insulating dielectric region 22 are distorted, resulting in a higher breakdown voltage than that of a semiconductor device without the insulating dielectric region 22.

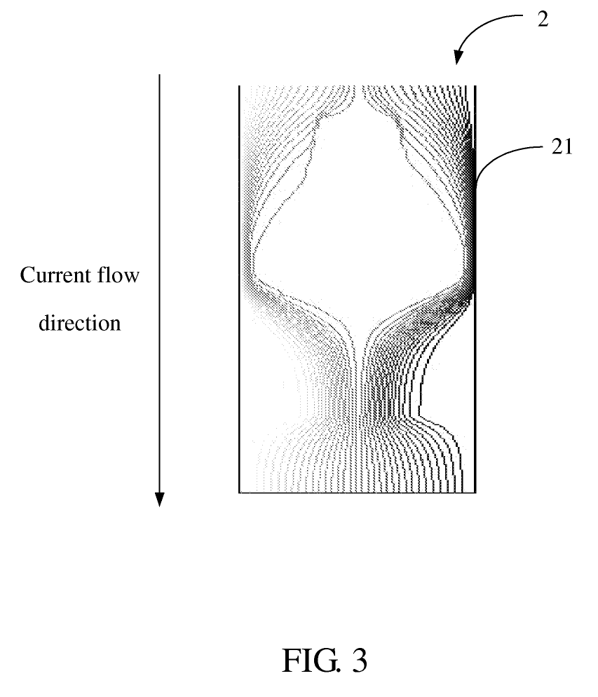

As can be seen clearly from FIG. 3, the current flow in the semiconductor region 21 distorts when an electric field is applied. In FIG. 3, the vertical axis represents the current flow direction when a breakdown occurs, while the horizontal axis represents the lateral dimension of the semiconductor device structure 2. As clearly shown in the current simulation diagram, the location and geometry shape of the insulating dielectric region 22 cause a corresponding variation of the current flow direction. Since the insulating dielectric region 22 is arranged inside the semiconductor device structure 2 in this embodiment, the current flows towards the peripheral areas of the device. As compared to the semiconductor device structure 2 without an insulating dielectric region, the slight increase in the length of the current flow path causes a corresponding slight increase in the turn-on impedance; however, the breakdown voltage is increased remarkably. The relative relationships between the breakdown voltage and the turn-on impedance will be explained in detail hereinafter.

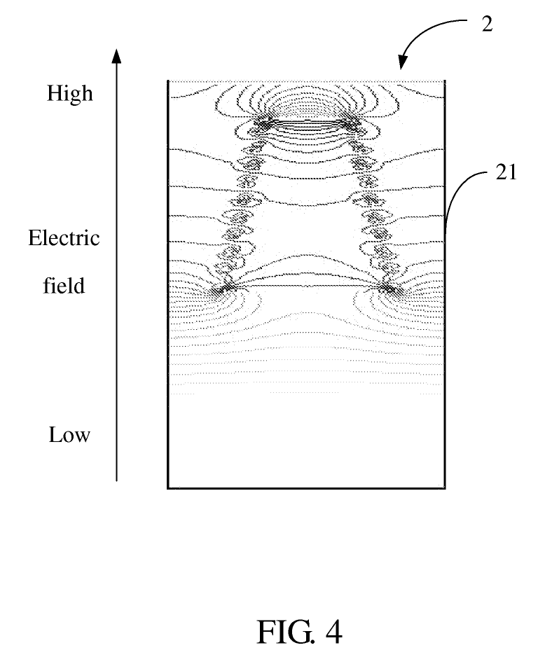

As shown in FIG. 4, the electric field in the semiconductor region 21 also has a two-dimensional distribution. In other words, the electric field variation occurs in both the longitudinal and the lateral direction in portions of the semiconductor device structure 2 near the insulating dielectric region 22. Hence, the insulating dielectric region 22 may cause a change in the direction of the electric field in the semiconductor region 21, thus modulating the electric field into a two-dimensional or even the three-dimensional electric field. Nevertheless, the insulating dielectric region 22 has no adverse influence on the current flow as long as it does not block the entire current flow path. In a cross section perpendicular to the longitudinal direction H1 of this embodiment, for example, a sub-section needed for the current to flow through is determined by the sub-section of the insulating dielectric region 22 arranged in the semiconductor region 21. Therefore, by designing the two subsections in an appropriate ratio, a smooth current flow may be achieved.

In FIG. 4, the vertical axis represents the electric field distribution, while the horizontal axis represents a lateral dimension of the semiconductor device structure 2. As can be seen from FIG. 4, by arranging the insulating dielectric region 22, the electric field is changed significantly into a two-dimensional or even three-dimensional distribution. It can be seen clearly from FIG. 4 that the distribution of the electric field experiences variation in both the longitudinal and the lateral direction near the insulating dielectric region 22, and the strong electric field region shifts to the peripheral region of the insulating dielectric region 22. Furthermore, silica is known to withstand a critical electric field strength of 10⁷ V/cm in theory, which is 33.3 times compared to that of silicon (3×10⁵ V/m). Therefore, if the insulating dielectric region 22 is made of silica, the semiconductor device structure 2 of this invention will be able to withstand a higher electric field, thus obtaining a higher breakdown voltage. Then, by shrinking the longitudinal dimensions of the device or increasing the doping level of extrinsic atoms in the semiconductor region, the turn-on impedance can be decreased.

Accordingly, compared to the semiconductor device structure without an insulating dielectric region, the necessary length of the semiconductor device structure 2 in this embodiment may be reduced in the longitudinal direction (i.e., the current flow direction) to design a semiconductor device structure with the same breakdown voltage. The smaller length of the semiconductor region will yield a shorter current flow path. Therefore, as per Equation 2, the turn-on impedance will be effectively decreased under the same breakdown voltage.

To further illustrate effect of this invention, the dimensions of the insulating dielectric region 22 in this embodiment are modulated in Table 1 to simulate the influence on the breakdown voltage and the turn-on impedance. In this table, the reference value represents the turn-on impedance and the breakdown voltage of the semiconductor device structure 2 when the semiconductor region 21 does not comprise the insulating dielectric region 22, i.e., when H2, W2 and W3 all have a zero value. Here, it is assumed that the first longitudinal dimension H1 of the semiconductor region 21 is 70 μm, and the first lateral dimension W1 is 25 μm.

TABLE 1

| | | Structure I | Structure II | Structure III |
|---|---|---|---|---|
| | | W2 = 5 μm | W2 = 6 μm | W2 = 8 μm |
| | Reference | W3 = 10 μm | W3 = 12 μm | W3 = 16 μm |
| | value | H2 = 30 μm | H2 = 30 μm | H2 = 30 μm |
| Turn-on | 100% | 101.56% | 104.43% | 112.02% |
| impedance | | | | |
| Breakdown | 100% | 117.89% | 121.84% | 130.05% |
| voltage | | | | |

As indicated in Table 1, the breakdown voltage and the turn-on impedance of the semiconductor device structure 2 change as a function of the dimensions of the insulating dielectric region 22.

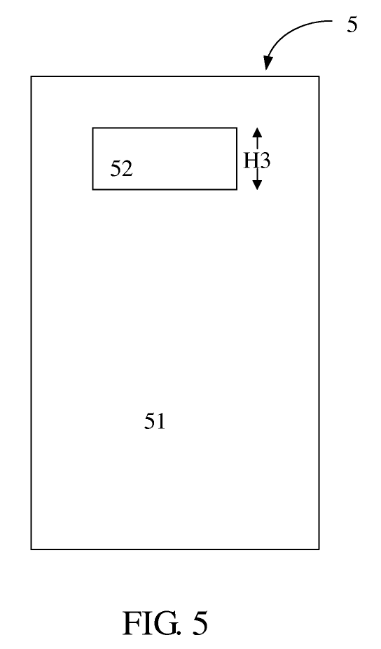

FIG. 5 illustrates the preferred embodiment of this invention, where an insulating dielectric region 52 different from that shown in FIG. 2 is disposed within the semiconductor region 51 of a semiconductor device structure 5. In this embodiment, the insulating dielectric region 52 is shaped into a cuboid with a third longitudinal direction H3. In this embodiment, the semiconductor region 51 has a longitudinal dimension of 70 μm and a lateral dimension of 25 μm. As indicated in Table 2, by modulating the dimension H3, the breakdown voltage and the turn-on conductance of the semiconductor device structure 5 both are modulated.

TABLE 2

| | H3 (μm) | | | | | | |
|---|---|---|---|---|---|---|---|
| | 0 | 5 | 10 | 20 | 30 | 40 | 50 |
| Turn-on impedance | 100% | 101.38% | 102.36% | 103.77% | 105.24% | 107.6% | 111.6% |
| Breakdown voltage | 100% | 78.5% | 97.1% | 107.06% | 117.89% | 126.27% | 131.36% |

It follows from the above two embodiments that the breakdown voltage and turn-on impedance of a semiconductor device structure may be modulated by altering the shape of an insulating dielectric region in the semiconductor region. Similarly, the electric field of the semiconductor region may be modulated into at least a two-dimensional field by altering the number and relative positions of the insulating dielectric region, for example, by forming a plurality of insulating dielectric regions made of the same or different insulating materials. Thus, it is also possible to modulate the breakdown voltage and the turn-on impedance of the semiconductor device structure.

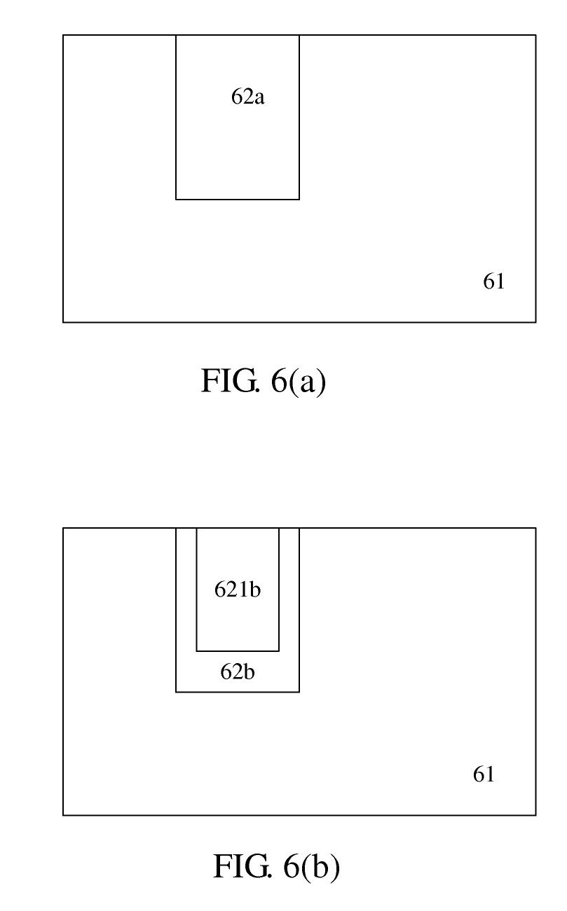

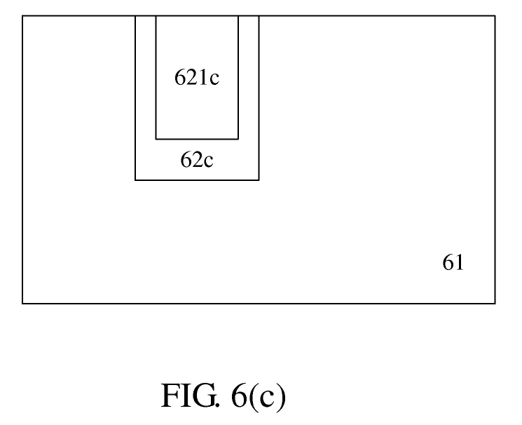

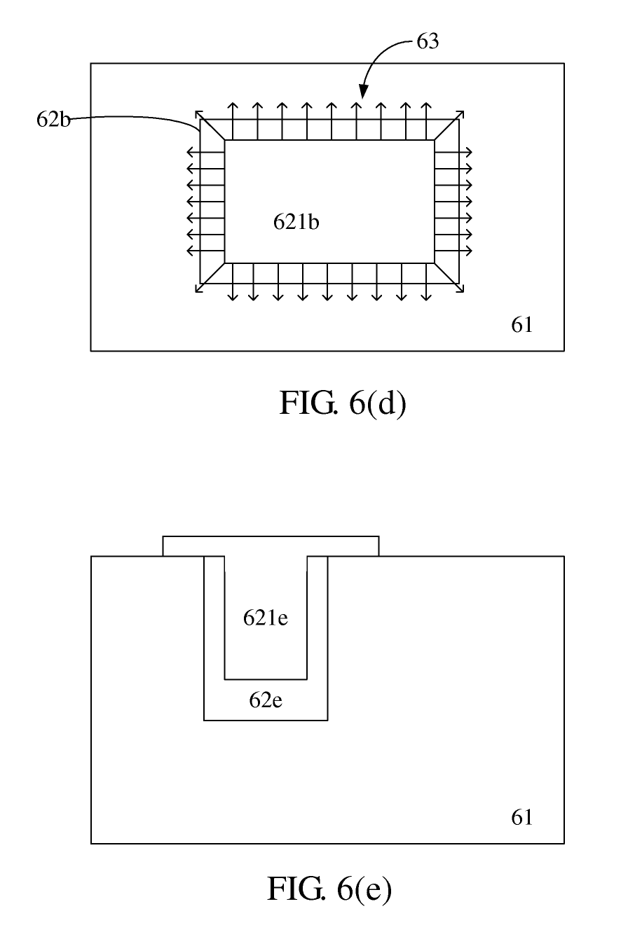

To produce a semiconductor device structure with a semiconductor region that comprises an insulating dielectric region, a trench manufacturing process may be used to form an interval space on the semiconductor region, and then an insulating dielectric material is formed in the interval space, as shown in FIG. 6(a), FIG. 6(b) and FIG. 6(c). Here, the insulating dielectric region may also comprise other materials. The structure shown in FIG. 6(a) has a semiconductor region 61 and an insulating dielectric region 62a, the structure shown in FIG. 6(b) has a semiconductor region 61 and an insulating dielectric region 62b which further comprises a conductive layer 621b. The structure shown in FIG. 6(c) has a semiconductor region 61 and an insulating dielectric region 62c which further comprises a polycrystalline semiconductor layer 621c. In the trench process, an interval space is formed by removing a portion of the semiconductor region that is intended for the insulating dielectric region by physical etching or dry etching. For example, the trench process may be one of a shallow trench process, a deep trench process, a through-silicon-via (TSV) process, and a combination thereof.

Next, FIG. 6(d) illustrates the top view of the embodiment. Because the conductive layer 621b is floating, there is a change in potential when a voltage is applied to the semiconductor region 61. Such a change in potential is associated with the location of the conductive layer 621b in the semiconductor region 61. Because the conductive layer 621b is formed on the insulating dielectric region 62b, the change in potential will induce electric charges around the insulating dielectric region 62b, causing an electric field 63 directed in all directions. Hence, the arrangement of the insulating dielectric region 62b and the conductive layer 621b in the semiconductor region 61 imposes an influence on the electric field distribution, and modulates the electric field of the semiconductor region 61 into a two-dimensional or a three-dimensional distribution. Similarly, the polycrystalline semiconductor layer 621c also plays the same role as the conductive layer 621b, and modulates the electric field of the semiconductor region 61 into a two-dimensional or a three-dimensional distribution.

FIG. 6(e) illustrates another embodiment of this invention. When a polycrystalline semiconductor layer or a conductive layer is formed, the polycrystalline semiconductor layer or the conductive layer may also cover a portion of the semiconductor region in addition to the original trench location. In this figure, a polycrystalline semiconductor layer 621e formed within the insulating dielectric region 62e is illustrated as an example. Such a polycrystalline semiconductor layer 621e covering a portion of the semiconductor region 61 may be formed by depositing outside the original location or by means of a polysilicon gate mask. The polycrystalline semiconductor layer 621e covering a portion of the semiconductor region 61 may act as an electrode of a floating electric field to alleviate the electric field that has accumulated on the surface of the semiconductor region 61 to increase the breakdown voltage.

In the embodiments shown in FIG. 6(b), FIG. 6(c) and FIG. 6(e), to help increase the breakdown voltage, a bias may also be applied to the polycrystalline semiconductor layer or the conductive layer to modulate the electric field distribution in the semiconductor region 61.

In all the aforesaid embodiments, the insulating dielectric region may span across the entire semiconductor region. For example, as shown in FIG. 2, the third lateral dimension W3 may be equal to the first lateral dimension W1 of the semiconductor region 21. A smooth current flow can be ensured as long as the sub-section for the current to flow through is maintained in the cross section of the semiconductor region 21 perpendicular to the longitudinal direction thereof. Furthermore, the interval space may not be filled with any other materials, but remains filled with air or in a vacuum, which may also substantially obtain the insulating effect and provide at least a two-dimensional electric field in the semiconductor region.

According to the above disclosure, by arranging at least an insulating dielectric material in the semiconductor region, the electric field distribution in the semiconductor region is modulated from one-dimensional to two-dimensional or even three-dimensional to increase the breakdown voltage of the device. Meanwhile, the turn-on impedance is decreased by shortening the length or increasing the doping level of the semiconductor region. Furthermore, this invention allows the use of a simple manufacturing process, and can be manufactured through a semiconductor manufacturing process that incorporates a trench forming step.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A semiconductor device structure for a semiconductor device having a breakdown voltage, the semiconductor device structure comprising:
a semiconductor region, presenting an electric filed when being applied with a voltage; and
an insulating dielectric region formed in the semiconductor region for modulating an electric force distribution in the semiconductor region;
thereby when the semiconductor region is applied with a voltage, the electric force distribution in the semiconductor region nearby the insulating dielectric region is distorted to cause a higher breakdown voltage referring to a simple breakdown voltage of a semiconductor device without the insulating dielectric region.

2. The semiconductor device structure as claimed in claim 1, wherein the semiconductor region is provided with a longitudinal direction, and along with a cross section crossing the insulating dielectric region and perpendicular to the longitudinal direction, a sub section for the current in the semiconductor region to flow through and a sub section occupied by the insulating dielectric region are in a certain ratio.

3. The semiconductor device structure as claimed in claim 1, wherein the semiconductor region is doped with extrinsic atoms.

4. The semiconductor device structure as claimed in claim 1, wherein the insulating dielectric region is an interval space.

5. The semiconductor device structure as claimed in claim 1, wherein material of the insulating dielectric region is selected from groups of: silica, silicon nitride, high-dielectric coefficient materials for use of semiconductor manufacturing, and low-dielectric coefficient materials for use of semiconductor manufacturing.

6. The semiconductor device structure as claimed in claim 1, wherein the semiconductor region is provided with a first longitudinal dimension, and the insulation dielectric region is provided with a second longitudinal dimension, the second longitudinal dimension is smaller than or equal to the first longitudinal dimension.

7. The semiconductor device structure as claimed in claim 1, wherein the semiconductor region is provided with a first lateral dimension, and the insulating dielectric region is provided with a second lateral dimension, the second lateral dimension is small than or equal to the first lateral dimension.

8. The semiconductor device structure as claimed in claim 7, wherein the insulating dielectric region is further provided with a third lateral dimension which is smaller than or equal to the first lateral dimension.

9. The semiconductor device structure as claimed in claim 1, further comprising a conductive layer formed in the insulating dielectric region.

10. The semiconductor device structure as claimed in claim 1, further comprising a polycrystalline semiconductor layer formed in the insulating dielectric region.

11. The semiconductor device structure as claimed in claim 1, further comprising a plurality of insulating dielectric regions.

12. The semiconductor device structure as claimed in claim 11, wherein the insulating dielectric regions are made of different insulating materials.

13. The semiconductor device structure as claimed in claim 1, wherein the insulating dielectric region is formed by executing a trench process, and the trench process comprising the steps of forming an interval space by removing portion of the semiconductor region, and forming the insulating dielectric material in the interval space.

14. The semiconductor device structure as claimed in claim 13, wherein the trench process is selected from one of a shallow trench process, a deep trench process, through silicon via (TSV) process, and a combination thereof.

15. The semiconductor device structure as claimed in claim 9, wherein the conductive layer covers portion of the semiconductor region.

16. The semiconductor device structure as claimed in claim 10, wherein the polycrystalline semiconductor layer covers portion of the semiconductor region.
